(19) United States
(12) Patent Application Publication
(10) Pub. No.: US 2010/0176790 A1
(43) Pub. Date: Jul. 15, 2010

(54) Testing Method and Device for a Wireless Receiver

(76) Inventor: Chu-Hsin Tsao, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 12/426,272

(22) Filed: Apr. 19, 2009

(30) Foreign Application Priority Data
Jan. 15, 2009 (TW) 098101363

(51) Int. Cl. G01R 23/16

(52) U.S. Cl. 324/76.21

(57) ABSTRACT

A testing method for a wireless receiver includes processing a test signal to generate an in-phase and a quadrature signal, performing a Fourier transform process to the in-phase signal and the quadrature signal to generate a first transformation result and a second transformation result, and displaying the first transformation result and the second transformation result by means of graphic, to generate a test result corresponding to the test signal.

### BACKGROUND OF THE INVENTION

1. Field of the Invention

The present invention relates to a testing method and device for a wireless receiver, and more particularly, to a testing method and device capable of instantaneously and accurately determining frequency bands and strength of noise or interference.

2. Description of the Prior Art

In modern Information society, various wireless communication networks have become one of the most important ways of exchanging voice, text, data, and video for many people. Generally, a user can access the wireless networks via a wireless network card, for example. Therefore, how to increase reception and transmission efficiency and reliability of the wireless network card becomes a goal in the industry.

In the prior art, a super heterodyne receiver is the most widespread use wireless communication receiver, which can execute carrier frequency adjustment, filtering, and amplifying. Therefore, the superheterodyne receiver is not only utilized to receive wireless signals for the wireless network, but also for satellite, broadcasting, mobile communication, etc.

Please refer to FIG. 1, which is a schematic diagram of a super heterodyne receiver 10 according to the prior art. The superheterodyne receiver 10 includes an antenna 100, a low noise amplifier 102, an image reject filter 104, a mixer 106, a local oscillator 108, an intermediate frequency (IF) low pass filter 110, an IF amplifier 112, and a baseband processor 114. Operations of the superheterodyne receiver 10 are well-known for those skilled in the art; thus, below is a summary of an operation method of the superheterodyne receiver 10. A radio-frequency (RF) signal V_{RF1} is received by the antenna 100, and is amplified to an RF signal V_{RF2} via the low noise amplifier 102. Then, the image reject filter 104 filters out image frequency signals of the RF signal V_{RF2} to generate a filtered RF signal VF_{RF}. The filtered RF signal VF_{RF} is transformed to an IF band through the mixer 106 to output IF signal V_{IF} to the baseband processor 114 via filtering of the IF low pass filter 110 and amplifying of the IF amplifier 112. After the baseband processor 114 receives the IF signal V_{IF}, depending on applications or requirements, the IF signal V_{IF} is processed by operations, such as demodulation, decoding, demultiplexing, etc., to obtain a message within the IF signal V_{IF}.

Generally, in addition to environment noise or interference, a main factor affecting reception and transmission efficiency of the superheterodyne receiver 10 is noise generated by inner elements. This kind of noise is caused by a flaw of a process or mismatch of the elements. For example, if the superheterodyne receiver 10 is utilized for a wireless network card, a motherboard, monitor, etc. of a notebook may generate noise when the wireless network card is utilized in the notebook for receiving wireless network signals. If the generated noise falls to a reception range of the wireless network card, and strength of the noise is greater than reception ability of the wireless network card, the generated noise affects reception and transmission efficiency of the wireless network card in a certain degree, and thereby impacts the overall performance and stability of the notebook. In order to prevent the abovementioned situation, a spectrum analyzer is utilized in the prior art for scanning wireless network frequency bands. However, this method only approximately knows which frequency band may have a problem, but cannot precisely know a level of the noise affecting a wireless network device. Therefore, a misdiagnosis might be occurred, and reception efficiency of the wireless network card cannot be improved.

### SUMMARY OF THE INVENTION

Therefore, the present invention provides a testing method and device for a wireless receiver.

The present invention discloses a testing method for a wireless receiver. The testing method includes processing a test signal to generate an in-phase and a quadrature signal, performing a Fourier transform process to the in-phase signal and the quadrature signal to generate a first transformation result and a second transformation result, and displaying the first transformation result and the second transformation result by means of graphic, to generate a test result corresponding to the test signal.

The present invention further discloses a testing device for a wireless receiver. The testing device includes a receiving unit for processing a test signal to generate an in-phase and a quadrature signal, a transforming unit for performing a Fourier transform process to the in-phase signal and the quadrature signal to generate a first transformation result and a second transformation result, and a display unit for displaying the first transformation result and the second transformation result by means of graphic, to generate a test result corresponding to the test signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a superheterodyne receiver according to the prior art.

FIG. 2 is a schematic diagram of a testing process according to an embodiment of the present invention.

FIG. 3A and 3B are schematic diagrams of a testing device according to an embodiment of the present invention.

FIGS. 4-7 are schematic diagrams of testing results according to an embodiment of the present invention.

### DETAILED DESCRIPTION

In order to test the noise or interference of a wireless receiver, the present invention utilizes an in-phase and a quadrature signal, which are widely used in the communication field, to accurately and quickly determine a frequency band which may have a problem, so as to enhance the stability of a product.

As well known by the industry, a band-pass signal x(t) can be represented by:

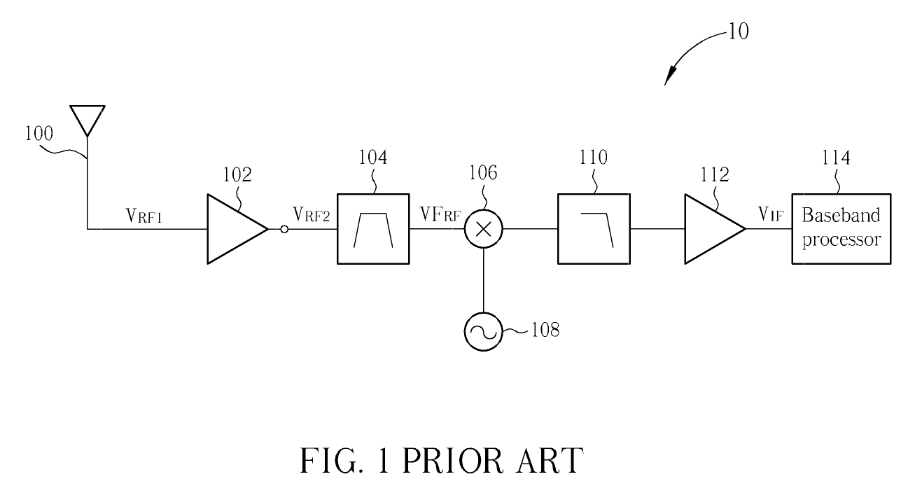

x(t)=x_{I}(t)*cos(2π*f_{C}*t)−x_{Q}(t)*sin(2π*f_{C}*t),

where x_{I}(t) is the in-phase part of the band-pass signal x(t), x_{Q}(t) is the quadrature part of the band-pass signal x(t), and f_{C} is the center frequency of the band-pass signal x(t). The in-phase signal and the quadrature signal reveal strength and phase change of a sine wave, and can be used for processing modulation signal or applying to a process of signal modulation. Please note that, a concept or a method of generating the in-phase signal and the quadrature signal are well-known by the industry, and are commonly seen in the communication system (such as the baseband processor 114 shown in FIG. 1).

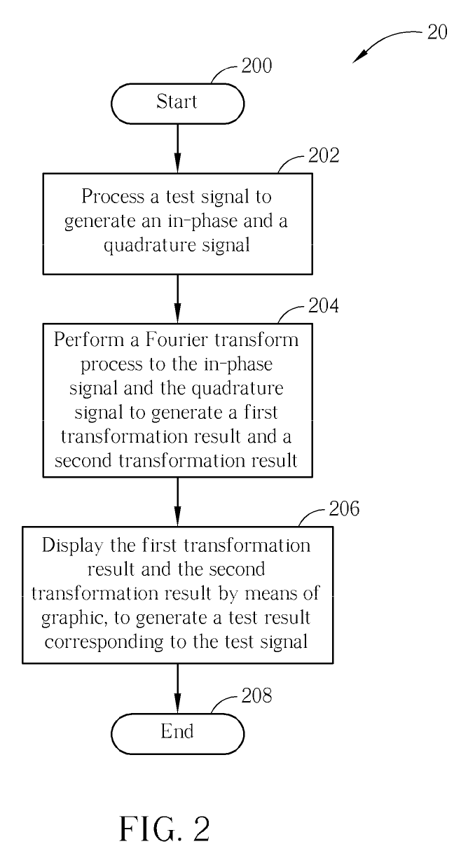

Next, an operation method of the present invention is described herein. Please refer to FIG. 2, which is a schematic diagram of a testing process 20 according to an embodiment of the present invention. The testing process 20 is utilized in a wireless receiver, which includes the following steps:

Step 200: Start.

Step 202: Process a test signal to generate an in-phase and a quadrature signal.

Step 204: Perform a Fourier transform process to the in-phase signal and the quadrature signal to generate a first transformation result and a second transformation result.

Step 206: Display the first transformation result and the second transformation result by means of graphic, to generate a test result corresponding to the test signal.

Step 208: End.

According to the process 20, the wireless receiver processes the test signal to generate the in-phase and the quadrature signal. Then, the present invention performs the Fourier transform process on the in-phase signal and the quadrature signal to generate the test result via displaying the transformation results. Since the Fourier transform process transforms a time domain to a frequency domain, the test result displayed by the process 20 is corresponding to the frequency domain, and thereby the operator can quickly observe which frequency bands have noise or interference, so as to take related actions to enhance the stability of the product.

Please note that, in step 202, a way of generating the in-phase and the quadrature signal is not limited herein, which is ordinary skill in the prior art. For example, the in-phase signal can be obtained via multiplying the test signal by cos(2π*f_{C}*t), and then goes through low-pass filtering to generate the in-phase signal. The quadrature signal can be obtained via multiplying the test signal by (−sin(2π*f_{C}*t)), and then goes through low-pass filtering to generate the quadrature signal. Since the in-phase and the quadrature signal are often used in a baseband process, the present invention only needs to capture the in-phase and the quadrature signal generated by the baseband processor 114, and do not need additional steps.

In addition, in step 204, the in-phase and the quadrature signal are processed by the Fourier transform process, to transform a time domain signal to a frequency domain signal. Preferably, in order to enhance transformation efficiency, in step 204, the in-phase and the quadrature signal can be transformed to a first digital data and a second digital data first. Then, the first digital data and the second digital data are executed by a Fast Fourier transform process, to generate the first transformation result and the second transformation result. By the Fast Fourier transform process, an information (a content of the first digital data and the second digital data) of signal strength of the in-phase signal and the quadrature signal with respect to time can be transformed to an information (a content of the first transformation result and the second transformation result) of power spectrum strength with respect to time.

Finally, since the first transformation result and the second transformation result are corresponding to the information of power spectrum strength of the in-phase signal and the quadrature signal with respect to frequency, by step 206, the first transformation result and the second transformation result can be displayed by means of graphic, and thereby the operator can estimate a state of noise or interference corresponding to a frequency band. In addition, when a test result is displayed, a criterion measurement graph can be displayed simultaneously for comparing with the test result, to make the operator to estimate noise or interference more easily.

Moreover, during the testing process, in order to simulate all the possible states of noise generating in the wireless receiver, amplifying capability of the wireless receiver is fixed to a maximum value, and the in-phase signal and the quadrature signal are continuously updated. For example, operation is captured and measurement graph is updated every 0.5 second (namely twice per second), to facilitate estimation instantaneously.

Therefore, the present invention can determine frequency bands of the wireless receiver, which may have problem, through the testing process 20, to take related measures for enhance stability of the product.

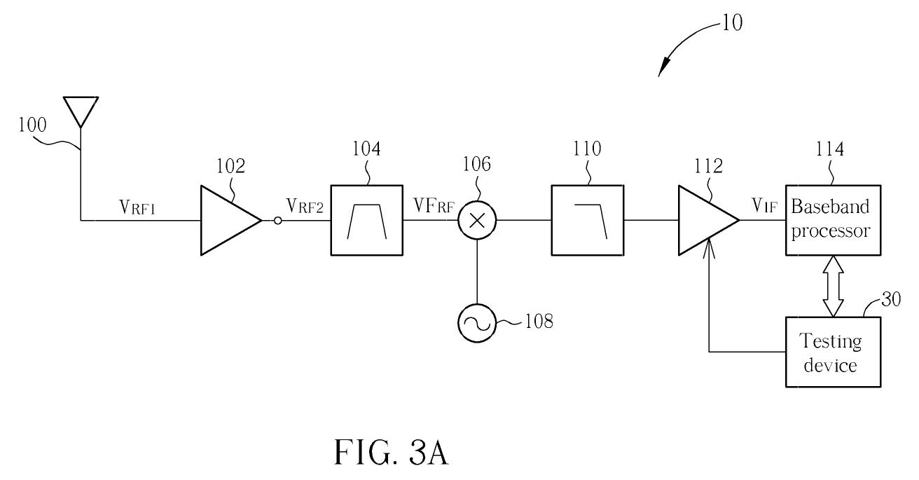

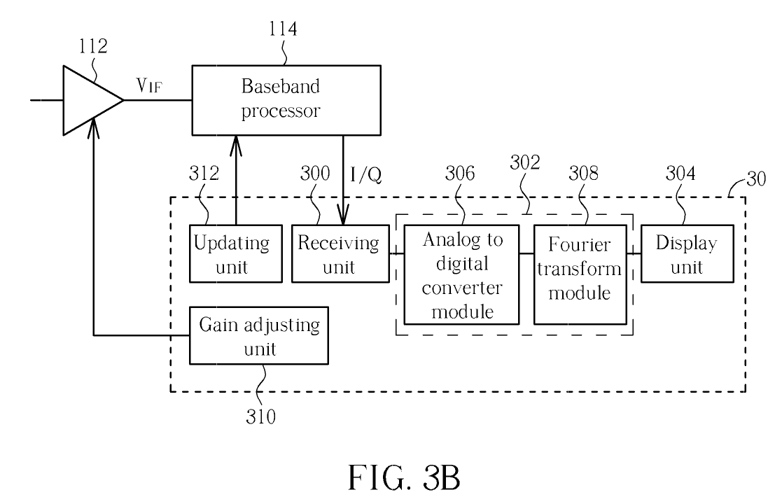

Upon implementation of the testing process 20, please refer to FIG. 3A and 3B. FIG. 3A is a schematic diagram of a testing device 30 utilized in the superheterodyne receiver 10 shown in FIG. 1 according to an embodiment of the present invention, and FIG. 3B is a functional block diagram of the testing device 30. The testing device 30 includes a receiving unit 300, a transforming unit 302, a display unit 304, a gain adjusting unit 310, and an updating unit 312. The testing device 30 is utilized for realizing the testing process 20, and an operation method can be referred to the foregoing description. Below is a summary of an operation method of the testing device 30. The receiving unit 300 is utilized for receiving the in-phase and the quadrature signal generated by the baseband processor 114. The transforming unit 302 includes an analog to digital converter module 306 and a Fourier transform module 308. The analog to digital converter module 306 is utilized for transforming the in-phase signal and the quadrature signal to digital data. The Fourier transform module 308 is utilized for performing the Fast Fourier transform process on the digital data to generate the corresponding transformation result in display unit 304, and then the display unit 304 displays the transformation result by means of graphic, to generate the corresponding test result. In addition, the gain adjusting unit 310 fixes amplifying capability of the IF amplifier to a maximum value, and the updating unit 312 updates the in-phase signal and the quadrature signal generated by the baseband processor 114 according to a predetermined frequency, so as to re-capture operation and update measurement graphs.

Note that, the testing device 30 shown in FIG. 3A and 3B is only utilized for illustrating a concept of the present invention. Those skilled in the art can make alternations and modifications accordingly, and is not limited herein.

Therefore, the present invention can utilize the in-phase signal and the quadrature signal generated by the baseband processor to generate the corresponding graphic test result, and the operator can determine noise or interference state instantaneously and accurately and take suitable measures. In comparison, the prior art just scans wireless network frequency bands via a spectrum analyzer, so a degree of noise effect cannot be known accurately. Therefore, the present invention indeed improves shortcomings of the prior art.

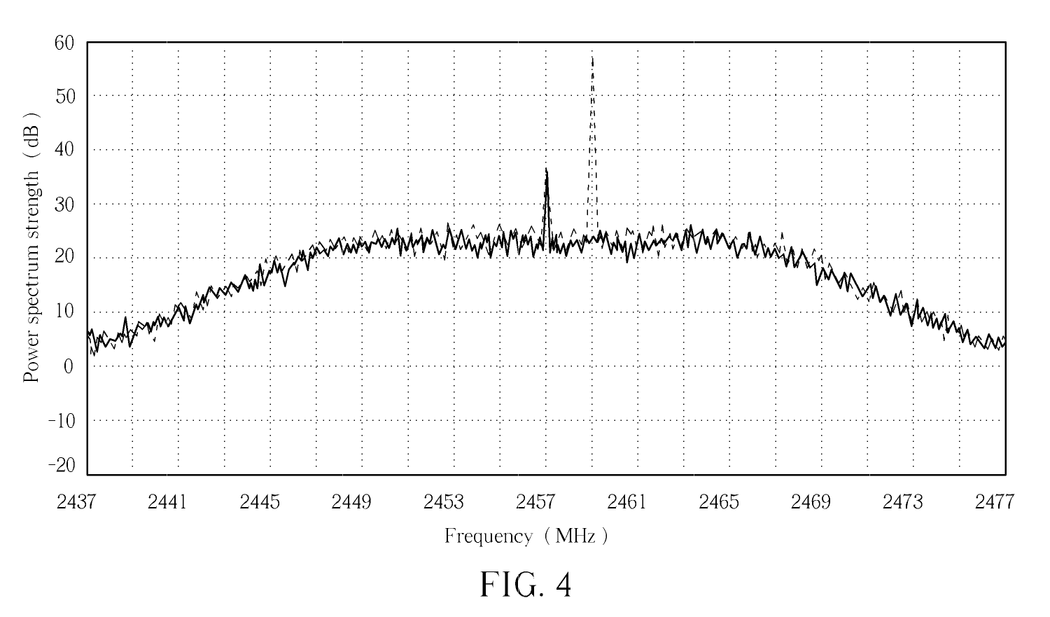

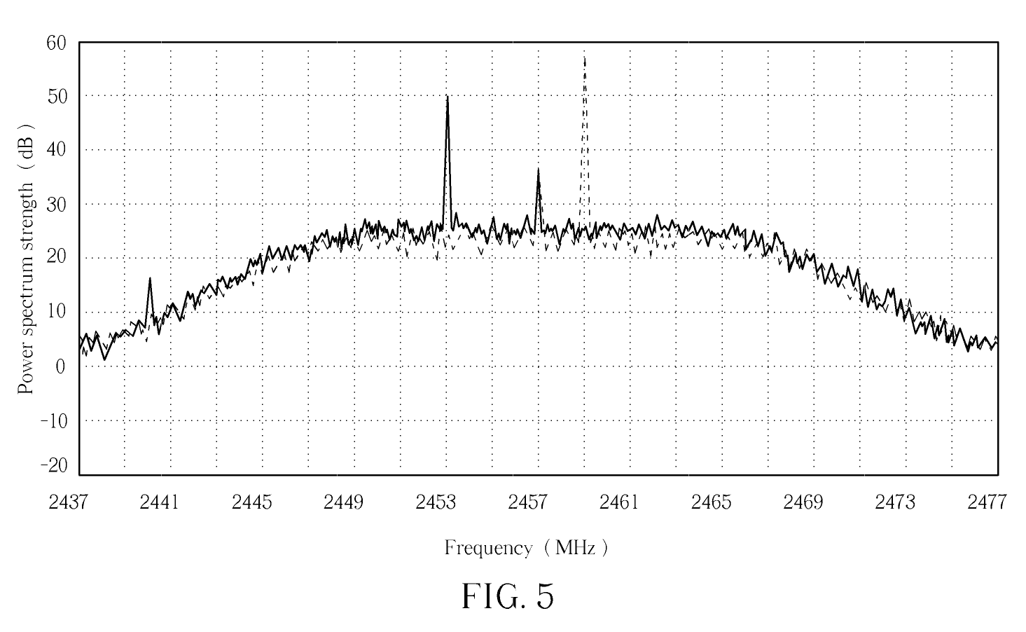

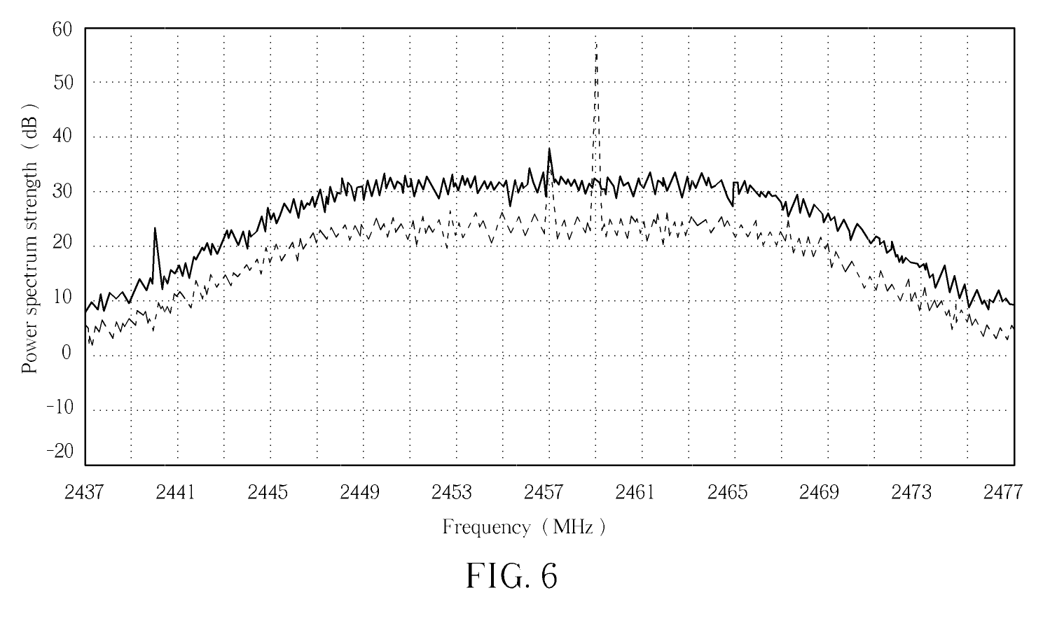

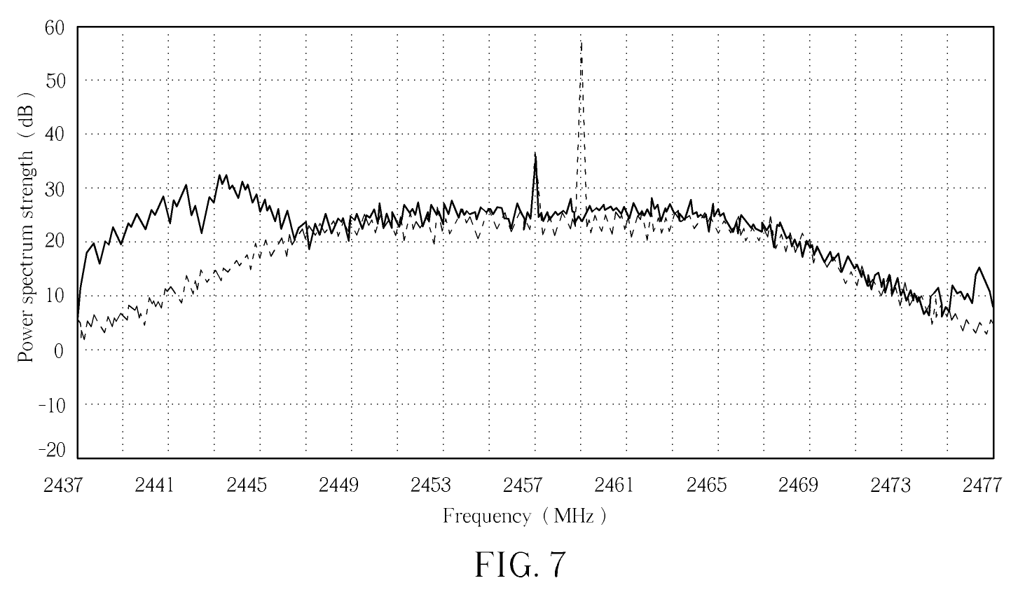

For example, please refer to FIG. 4˜7, which respectively display different test results in a structure of FIG. 3A. A curve depicted by a dotted line indicates criterion measurement graph, a prominent line indicates criterion signal strength which is predetermined to −86 dBm, and a curve depicted by a solid line indicates the test signal. Therefore, the operator can determine whether the superheterodyne receiver 10 operates correctly through graphic content shown in FIG. 4˜7. For example, in FIG. 5, a frequency of a test signal is 2453 MHz, and strength of the test signal is −94 dBm. As can be seen, from the curve depicted by the solid line, the test result conforms to characteristics of the test signal, which indicates the test result is worth referencing. In addition, in FIG. 6, from the curve depicted by the solid line, entire noise strength is 7.13 dB larger than a reference signal. Finally, in FIG. 7, the curve depicted by the solid line indicates an interference signal occurs from frequency 2437 MHz to 2457 MHz, which is 4 dB larger than the reference signal.

The abovementioned example is utilized for illustrating how to display the test result corresponding to the test signal via graphic interface, so the operator can determine noise or interference state instantaneously and accurately and take suitable measures for enhance stability of the product.

In conclusion, the present invention utilizes the in-phase signal and the quadrature signal generated by the baseband processor to generate the corresponding graphic test result. Therefore, the operator can determine frequency bands and strength of noise or interference instantaneously and accurately, so as to take suitable measures for enhance stability of the product.

Those skilled in the art will readily observe that numerous modifications and alterations of the device and method may be made while retaining the teachings of the invention.

What is claimed is:

1. A testing method for a wireless receiver comprising:
processing a test signal to generate an in-phase and a quadrature signal;
performing a Fourier transform process to the in-phase signal and the quadrature signal to generate a first transformation result and a second transformation result;
comparing the first transformation result and the second transformation result with a criterion data to generate a test result corresponding to the test signal; and
displaying the first transformation result and the second transformation result to generate a test result corresponding to the test signal.

2. The testing method of claim 1, wherein the step of performing the Fourier transform process on the in-phase signal and the quadrature signal to generate the first transformation result and the second transformation result comprises:
transforming the in-phase signal and the quadrature signal to a first digital data and a second digital data; and
performing the Fourier transform process on the first digital data and the second digital data to generate the first transformation result and the second transformation result.

3. The testing method of claim 2, wherein the first digital data corresponds to a signal strength of the in-phase signal with respect to time.

4. The testing method of claim 2, wherein the second digital data corresponds to a signal strength of the quadrature signal with respect to time.

5. The testing method of claim 2, wherein the first transformation result corresponds to a power spectrum of the in-phase signal with respect to frequency.

6. The testing method of claim 2, wherein the second transformation result corresponds to a power spectrum of the quadrature signal with respect to frequency.

7. The testing method of claim 2, wherein the Fourier transform process is a Fast Fourier transform process.

8. The testing method of claim 1, wherein the step of comparing the first transformation result and the second transformation result with the criterion data comprises:
displaying the first transformation result and the second transformation result by means of graphic to compare with a graphic of the criterion data.

9. The testing method of claim 1 further comprising fixing amplifying capability of the wireless receiver to a maximum value.

10. The testing method of claim 1 further comprising updating the in-phase signal and the quadrature signal generated by the wireless receiver according to a predetermined frequency.

11. A testing device for a wireless receiver comprising:
a receiving unit for processing a test signal to generate an in-phase and a quadrature signal;
a transforming unit for performing a Fourier transform process on the in-phase signal and the quadrature signal to generate a first transformation result and a second transformation result;
a compare unit for comparing the first transformation result and the second transformation result with a criterion data to generate a test result corresponding to the test signal; and
a display unit for generating a test result corresponding to the test signal.

12. The testing device of claim 11, wherein the transforming unit comprises:
an analog to digital converter module for transforming the in-phase signal and the quadrature signal to a first digital data and a second digital data; and
a Fourier transform module for performing the Fourier transform process on the first digital data and the second digital data to generate the first transformation result and the second transformation result.

13. The testing device of claim 12, wherein the first digital data corresponds to a signal strength of the in-phase signal with respect to time.

14. The testing device of claim 12, wherein the second digital data corresponds to a signal strength of the quadrature signal with respect to time.

15. The testing device of claim 12, wherein the first transformation result corresponds to a power spectrum of the in-phase signal with respect to frequency.

16. The testing device of claim 12, wherein the second transformation result corresponds to a power spectrum of the quadrature signal with respect to frequency.

17. The testing device of claim 12, wherein the Fourier transform process is a Fast Fourier transform process.

18. The testing device of claim 11, wherein the compare unit comprises:
a display unit for displaying the first transformation result and the second transformation result by means of graphic to compare with a graphic of the criterion data.

19. The testing device of claim 11 further comprising a gain adjusting unit for fixing amplifying capability of the wireless receiver to a maximum value.

20. The testing device of claim 11 further comprising an updating unit for updating the in-phase signal and the quadrature signal generated by the wireless receiver according to a predetermined frequency.
